(19) United States
(12) Patent Application Publication
(10) Pub. No.: US 2018/0257932 A1
(43) Pub. Date: Sep. 13, 2018

(54) MANUFACTURING METHOD FOR A MICROMECHANICAL DEVICE INCLUDING AN OBLIQUE SURFACE AND CORRESPONDING MICROMECHANICAL DEVICE

(71) Applicant: Robert Bosch GmbH, Stuttgart (DE)

(72) Inventors: Benjamin Steuer, Waldenbuch (DE); Christoph Schelling, Stuttgart (DE); Daniel Pantel, Ditzingen (DE); Stefan Pinter, Reutlingen (DE)

(21) Appl. No.: 15/914,092

(22) Filed: Mar. 7, 2018

(30) Foreign Application Priority Data
Mar. 8, 2017 (DE) 102017203753.9

(51) Int. Cl. B81C 1/00; G02B 26/08

(52) U.S. Cl. CPC B81C 1/00626; G02B 26/0833; B81C 2201/053; B81C 2201/0133; B81C 2201/016; B81C 2201/0123

(57) ABSTRACT

A method for manufacturing a micromechanical device includes providing a silicon substrate having a front side and a rear side, where a first normal of the front side deviates by a first angle from the <111> direction of the silicon substrate; forming in the front side first and second trenches that are spaced apart from and essentially parallel to each other, with the first and second trenches extending along a direction of the deviation; forming on the front side a first etching mask that covers the front side except for a first opening area between the first and second trenches; and anisotropically etching the front side using the etching mask, thereby forming in the opening area an oblique surface having a second angle to the first normal, which approximately corresponds to the first angle.

### CROSS-REFERENCE TO RELATED APPLICATIONS

The present application claims priority under 35 U.S.C. § 119 to DE 10 2017 203 753.9, filed in the Federal Republic of Germany on Mar. 8, 2017, the content of which is hereby incorporated by reference herein in its entirety.

### FIELD OF THE INVENTION

The present invention relates to a manufacturing method for a micromechanical device including an oblique surface and to a corresponding micromechanical device. Although the present invention and its underlying problem are described based on optical micromechanical micromirror scanner devices, the invention can also be applied to other optical devices.

### BACKGROUND

To achieve a high quality and thus a low power consumption for micromirror scanner devices, in particular for resonantly driven micromirror scanner devices, the micromirror must be hermetically packaged under a vacuum. The hermetic packaging additionally prevents soiling of the mirror. The entrance or exit window for the light used is implemented by an optical glass window. For this purpose, usually a small glass plate is bonded onto a silicon base, a so-called base chip, using seal glass. To ensure good hermeticity, preferably smooth surfaces are required at the bonding sites of the glass window and the silicon surface.

To avoid undesirable reflections, the optical window must have an angle, i.e., must be obliquely situated, with respect to the non-deflected mirror surface, i.e., the substrate surface.

Such windows can be implemented with the aid of deformation techniques or geometries in the silicon base, which are generated by milling, for example. These include rough surfaces and must be manufactured in a sequential process. In particular, a laser ablation process in a sequential process is also possible.

DE 10 2010 062 009 A1 describes a method for manufacturing oblique surfaces in a substrate, flexible diaphragms being applied over a recess, which are subsequently deformed.

DE 10 2010 062 118 A1 describes a cover device for a micromirror device which includes at least one window made up of a translucent material, which is attached to a substrate in such a way that at least one recess extending through the substrate is sealable with the aid of the respective window. The window is oriented at an incline with respect to a maximum surface of the substrate.

### SUMMARY

The present invention is directed to a manufacturing method for a micromechanical device including an oblique surface and to a corresponding micromechanical device.

The present invention enables the manufacture of a mechanically stable base chip for accommodating an oblique, in particular rectangular, window, having a preferably exact alignment and including preferably smooth surfaces. The present invention is based on the idea of combining anisotropic etching, e.g., KOH etching, on miscut <111>-oriented silicon wafers, i.e., silicon wafers in which the surface normal encloses an angle unequal to 0° with the <111> direction of the silicon, with trenches in the silicon substrate, the trenches or their walls being passivated against an etching attack with the aid of an etching mask. In this way, an oblique wedge-shaped cavity can be generated, which defines the oblique surface. In particular, the proposed process is tolerant with respect to excessively long etching in the anisotropic etching step. An essential advantage of the KOH process is the formation of smooth surfaces since the KOH etching process does not attack the <111> surfaces, and these are therefore atomically smooth.

The manufacturing method according to the present invention can be partially implemented as a batch process and thus represents a relatively cost-effective manufacturing method. The angle of the oblique surface to the substrate surface can be set very precisely by the mis-orientation of the silicon substrate.

According to one preferred refinement, a second normal of the rear side of the silicon substrate has the deviation by the first angle from the <111> direction in a direction opposite to the direction, the following further steps being carried out: forming a third trench and a fourth trench in the rear side, the third trench being spaced apart from the fourth trench essentially in parallel thereto, and the third trench and the fourth trench extending along the opposite direction; forming a second etching mask on the rear side, which covers the rear side except for a second opening area situated between the third trench and the fourth trench; simultaneously carrying out the anisotropic etching process on the rear side using the etching mask, whereby a further oblique surface is formed in the second opening area having the second angle to the normal, which approximately corresponds to the first angle, the further oblique surface extending essentially in parallel to the oblique surface.

In this way, two bevels can be formed simultaneously. This has the further advantage that one bevel is formed on both sides, so that the trench etching necessary during an optional formation of a through-opening has a lower thickness.

According to one further preferred refinement, the third trench extends in parallel to and laterally offset from the first trench, and the fourth trench extends in parallel to and laterally offset from the second trench. In this way, the bevels are approximately congruent, and undesirable boundary effects during anisotropic etching, in particular due to excessively long etching, can be avoided. An advantage of a “lateral offset” is that the trenches do not make contact with each other, even if the trench depth is larger than half the substrate thickness.

According to one further preferred refinement, the first opening area is essentially rectangular, extending up to the respective side edge and end edge of the first trench and of the second trench and/or the second opening area is essentially rectangular, extending up to the respective side edge and end edge of the third trench and of the fourth trench. The trenches can thus define straight lateral edges of the etching.

According to one further preferred refinement, the first etching mask fills the first trench and the second trench only partially and/or the second etching mask fills the third trench and the fourth trench only partially. In this way, the etching mask, for example, can be cost-effectively implemented using a thin silicon oxide layer and/or silicon nitride layer.

According to one further preferred refinement, the depth extension of the first trench and of the second trench is identical, the anisotropic etching process being carried out at most up to the depth extension. By carrying out the anisotropic etching process only up to the trench depth, the trenches define the etching width across the entire depth of the etching process.

According to one further preferred refinement, the depth extension of the third trench and of the fourth trench is identical to the depth extension of the first trench and of the second trench. In certain refinements, the anisotropic etching can also be deeper than the trenches.

According to one further preferred refinement, a through-opening through the silicon substrate is formed in a portion of the oblique surface, and an optical window is bonded onto the periphery of the portion of the oblique surface and/or a through-opening through the silicon substrate is formed in a portion of the further oblique surface, and an optical window is bonded onto the periphery of the portion of the further oblique surface. In this way, an oblique window structure may be created.

According to one further preferred refinement, the first opening area of the first etching mask and/or the second opening area of the second etching mask include(s) at least one narrowing area, which defines an etching allowance during the anisotropic etching. In this way, the etching mask is exposed as little as possible to the etching medium in the trenches (if the trenches are filled completely with the mask material).

According to one further preferred refinement, a fifth trench is formed in the front side, which adjoins end faces of the first trench and of the second trench, which are situated on a side opposite the direction of the deviation, and closes these end faces into a U shape. In this way, a step can be defined on the front side by the fifth trench, which offers advantages during later process steps.

According to one further preferred refinement, a sixth trench is formed in the rear side, which adjoins end faces of the third trench and of the fourth trench, which are situated on a side opposite the direction of the deviation, and closes these end faces into a U shape. In this way, a step can be defined on the rear side by the fifth trench, which offers advantages during later process steps.

According to one further preferred refinement, the first trench and the second trench widen and deepen in the direction of the deviation. Deepening trenches have the following advantage during etching from both sides that the trenches are implemented preferably deep from both sides, without the trenches from opposing substrate sides making contact.

According to one further preferred refinement, the third trench and the fourth trench widen and deepen in the opposite direction. In this way, the rear side bevel may already be predefined.

According to one further preferred refinement, the anisotropic etching process includes a KOH etching. Such an etching can be controlled particularly well. In particular, KOH etches silicon anisotropically, the <111> surfaces not being attacked. Mask structures made up of SiO₂ (silicon dioxide) and Si₃Na₄ (silicon nitride) are not significantly attacked by KOH. The resulting etching cavity is an oblique octahedral section in the case of a rectangular etching mask, the surface projection being an oblique hexagon. The formation of the undesirable corners outside the provided rectangle is suppressed by the first and second trenches since they would render the substrate unstable and result in an additional increased need for surface. The same applies to the third and fourth trenches.

Further features and advantages of the present invention are described hereafter based on specific example embodiments with reference to the figures, in which identical reference numerals denote identical or functionally equivalent elements.

### BRIEF DESCRIPTION OF THE DRAWINGS

FIGS. 1a-1j show schematic representations to illustrate a manufacturing method for a micromechanical device including an oblique surface and the corresponding micromechanical device according to a first example embodiment of the present invention.

FIGS. 2a-2f show schematic representations to illustrate a manufacturing method for a micromechanical device including an oblique surface and the corresponding micromechanical device according to a second example embodiment of the present invention.

FIG. 3 shows a schematic representation to illustrate a manufacturing method for a micromechanical device including an oblique surface and the corresponding micromechanical device according to a third example embodiment of the present invention.

FIGS. 4a-4d show schematic representations to illustrate a manufacturing method for a micromechanical device including an oblique surface and the corresponding micromechanical device according to a fourth example embodiment of the present invention.

FIGS. 5a and 5b show schematic representations to illustrate a manufacturing method for a micromechanical device including an oblique surface and the corresponding micromechanical device according to a fifth example embodiment of the present invention.

### DETAILED DESCRIPTION

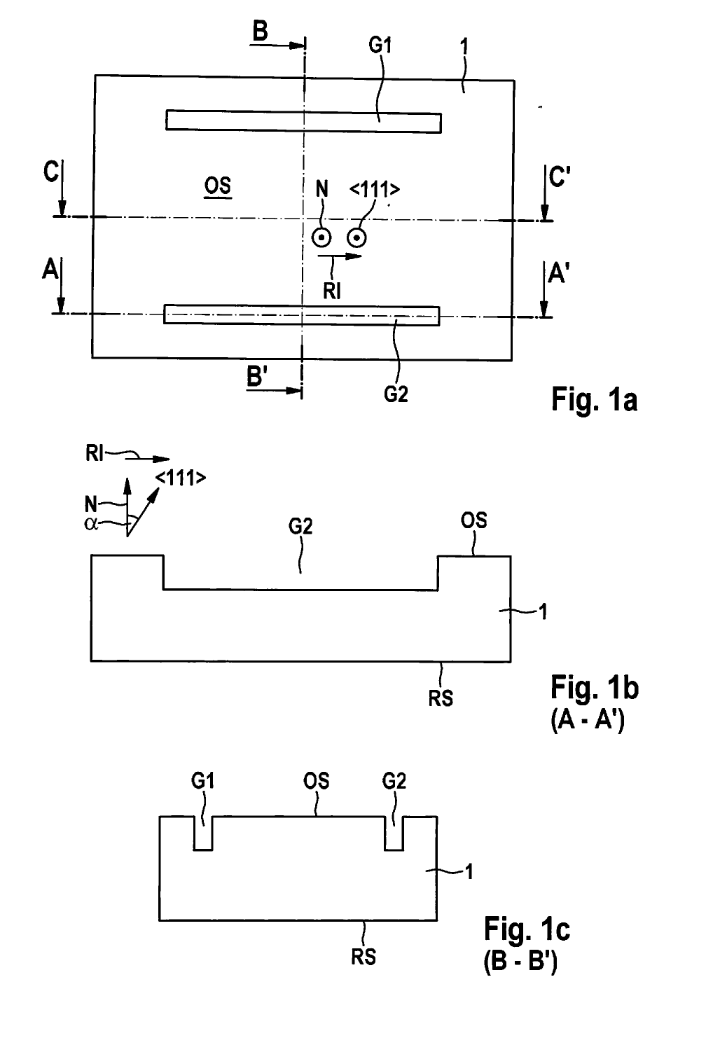

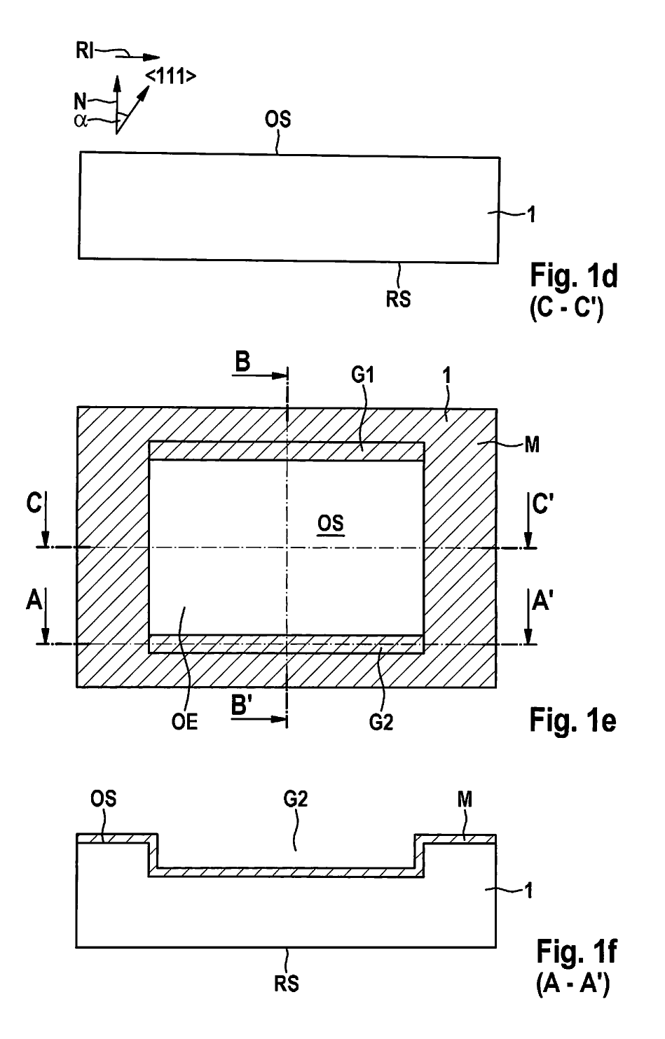

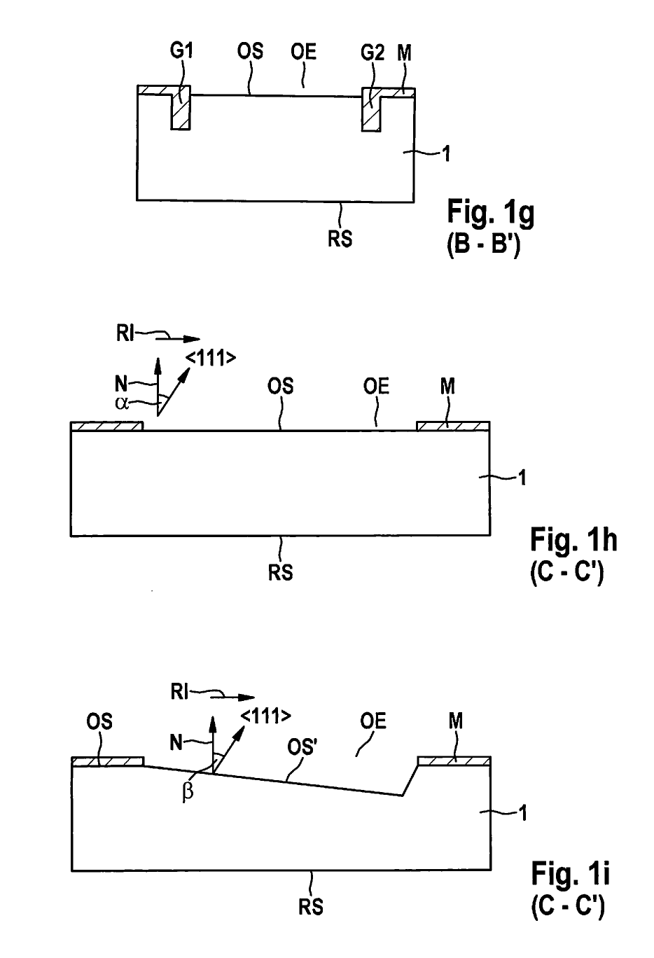

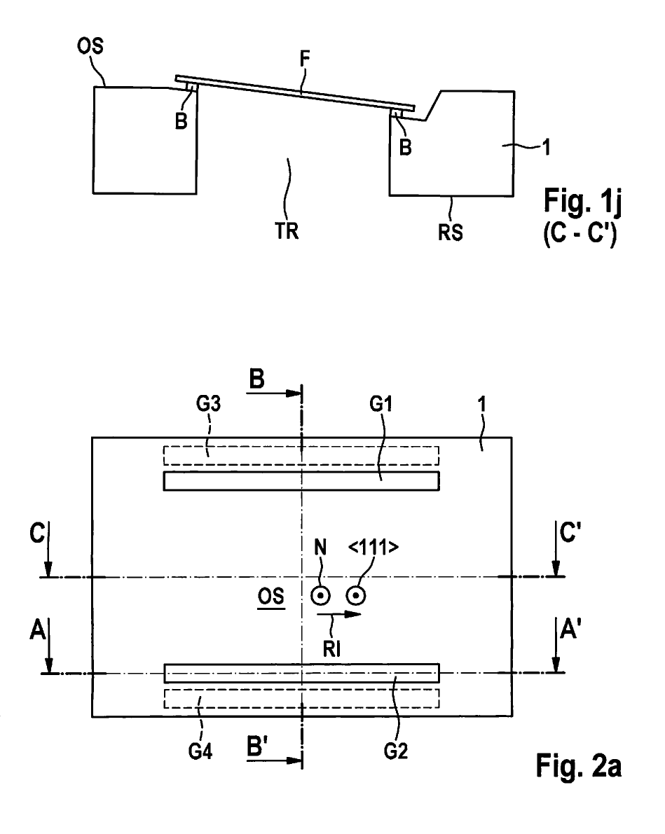

FIGS. 1a-1j are schematic representations that illustrate a manufacturing method for a micromechanical device including an oblique surface and the corresponding micromechanical device according to a first example embodiment of the present invention.

FIG. 1a shows a front side OS of a silicon substrate 1, a first normal N of front side OS having a deviation by a first angle a from the <111> direction of the silicon substrate. Angle α of the mis-orientation of silicon substrate 1 is typically 5° to 25°.

A first trench G1 and a second trench G2 are formed in front side OS, second trench G2 being spaced apart from first trench G1 essentially in parallel thereto, and first trench G1 and second trench G2 extending along a direction RI of the deviation. The depth of first trench G1 and of second trench G2 is typically 100 μm to 1000 μm, depending on the particular application area.

In the present exemplary embodiment, first trench G1 and second trench G2 are situated in such a way that they define a rectangle present in between.

Furthermore with reference to FIG. 1b, a vertical cross section through silicon substrate 1 along line A-A′ is shown, along which second trench G2 runs.

FIG. 1c shows a vertical cross section along line B-B′ of FIG. 1a, which shows first trench G1 and second trench G2 and which illustrates that a depth extension of first trench G1 and of second trench G2 is identical.

FIG. 1d shows a vertical cross section along line C-C′ of FIG. 1a.

After first trench G1 and second trench G2 have been created in front side OS of silicon substrate 1, for example in a trench or laser process, according to FIG. 1e a first etching mask M is formed on front side OS. Etching mask M covers front side OS except for an opening area OE, which is situated between first trench G1 and second trench G2 and corresponds to the rectangle situated between first trench G1 and second trench G2.

Etching mask M can be formed by a thin silicon dioxide layer and/or silicon nitride layer, which fills first trench G1 and second trench G2 only partially. On the other hand, the use of a thicker first etching mask M is also conceivable, which fills first trench G1 and second trench G2 completely. Combinations of silicon oxide, silicon nitride, and silicon carbide are also suitable for the mask. An isotropic, conformal deposition of the passivation or mask layer is preferred, for example with aid of a low-pressure chemical vapor deposition (LPCVD) process.

FIG. 1f shows a vertical section along line A-A′ of FIG. 1c. FIG. 1g shows a vertical section along line B-B′ of FIG. 1e, and FIG. 1h shows a vertical section along line C-C′ of FIG. 1e after formation of etching mask M.

In a subsequent process step, which is shown in FIG. 1i, an anisotropic etching process, using KOH as the etching medium, is carried out on front side OS, using etching mask M, up to the depth extension of first trench G1 and second trench G2. In certain specific embodiments, the etching process can also be carried out deeper than the depth of trenches G1, G2.

KOH etches the silicon anisotropically, the <111> surfaces not being attacked. Etching mask M made up of silicon dioxide or silicon nitride is not significantly attacked by KOH. The resulting etching cavity is an oblique rectangle since a lateral extension of the etching is prevented by first trench G1 and by second trench G2. The extension in the other two directions is limited by the (111) plane of the silicone substrate. In this way, an oblique surface OS′ is formed in opening area OE, opening area OE having a second angle β to first normal N, which exactly or at least approximately corresponds to first angle α.

As is shown in FIG. 1j, a through-opening TR through silicon substrate 1 is formed in a portion of oblique surface OS′ with the aid of trenching or lasering, and subsequently an optical window F is bonded onto the periphery of the portion of oblique surface OS′ with the aid of a bond frame B, for example made up of seal glass.

Such a silicon substrate 1 including an obliquely bonded optical window F is usable, for example, in a micromechanical micromirror scanner device, but is not limited to such a use.

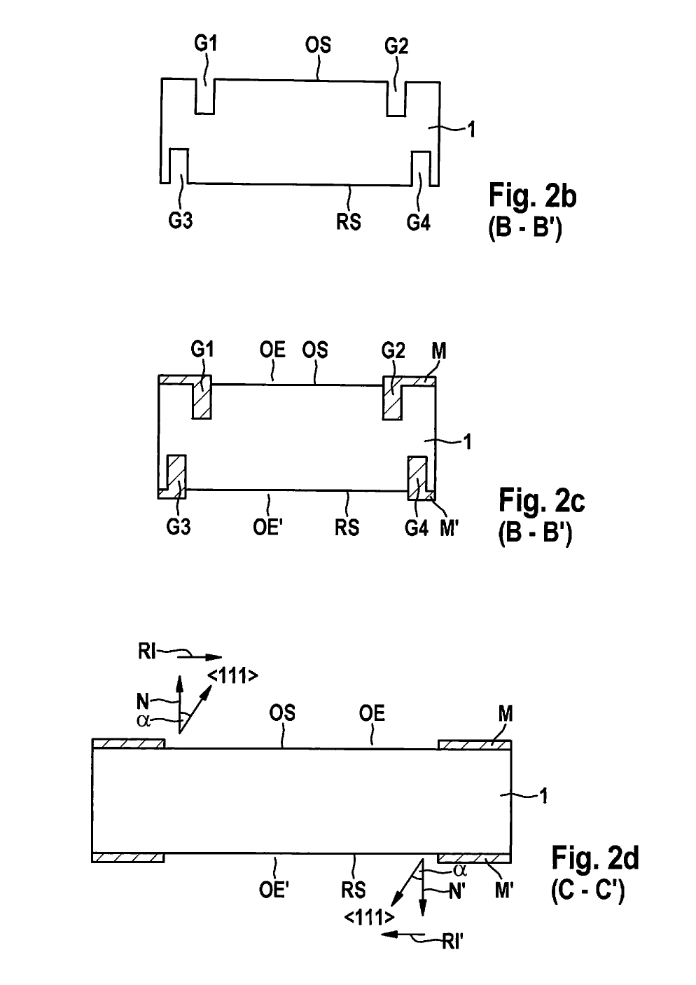

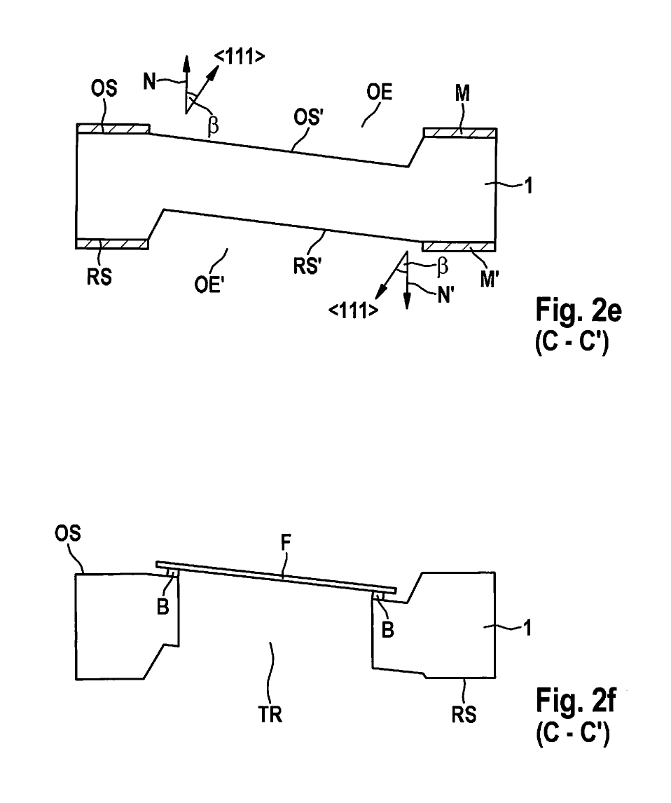

FIGS. 2a-2f are schematic representations to illustrate a manufacturing method for a micromechanical device including an oblique surface and the corresponding micromechanical device according to a second example embodiment of the present invention.

The illustration according to FIG. 2a corresponds to the illustration according to FIG. 1a, but in the second example embodiment a third trench G3 and a fourth trench G4 are provided in rear side RS, third trench G3 being spaced apart from fourth trench G4 essentially in parallel thereto, and third trench G3 and fourth trench G4 extending along opposite direction RI′ of the deviation, as is described in greater detail hereafter with reference to FIG. 2b.

FIG. 2b shows a vertical cross section along line B-B′ of FIG. 2a. Third trench G3 runs in parallel to and laterally offset from first trench G1, and fourth trench G4 runs in parallel to and laterally offset from second trench G2. The surface of rear side RS of silicon substrate 1 situated between third trench G3 and fourth trench G4 is also a rectangle, which has a larger width than the rectangle which is formed by the area of front side OS situated between first trench G1 and second trench G2.

A second normal N′ of rear side RS has the deviation by first angle a from the <111> direction in a direction RI′ opposite direction RI (cf. FIG. 2b).

In the second example embodiment, in addition to first etching mask M on front side OS, a second etching mask M′ is formed on rear side RS which covers rear side RS except for a second opening area OE′, which is situated between third trench G3 and fourth trench G4 and corresponds to the rectangle present in between, as shown in FIG. 2c, which shows a vertical cross section along line B-B′ in FIG. 2a.

FIG. 2d shows a vertical cross section along line C-C′ of FIG. 2a after first etching mask M and second etching mask M′ have been applied.

In the present example, a depth extension of third trench G3 and of fourth trench G4 is identical to the depth extension of first trench G1 and of second trench G2.

In the present second example embodiment, second etching mask M′ is also formed by a thin layer made up of silicon dioxide or silicon nitride and can preferably be formed in the same process step as first etching mask M on front side OS.

As is shown in FIG. 2e, subsequently the anisotropic KOH etching process is simultaneously carried out on front side OS and rear side RS, using first etching mask M and second etching mask M′, whereby a further oblique surface RS′ is formed in second opening area OE′ having second angle β to second normal N′, which exactly or at least approximately corresponds to first angle α. The further oblique surface RS′ thus formed therefore runs essentially in parallel to oblique surface OS′ on front side OS.

The fact that third trench G3 and fourth trench G4 are formed offset from first trench G1 and second trench G2 makes it possible to avoid undesirable boundary effects during excessively long anisotropic etching.

As with the above-described first example embodiment, a through-opening TR through silicon substrate 1 is formed in a portion of oblique surface OS′ or an opposing portion of further oblique surface RS′, and an optical window F is bonded onto the periphery of the portion of oblique surface OS′ with the aid of a bond frame. This results in the final process state shown in FIG. 2f.

Of course, optical window F could also be bonded onto the periphery of the portion of further oblique surface RS′ on rear side RS, or two optical windows F could each be provided on front side OS and rear side RS.

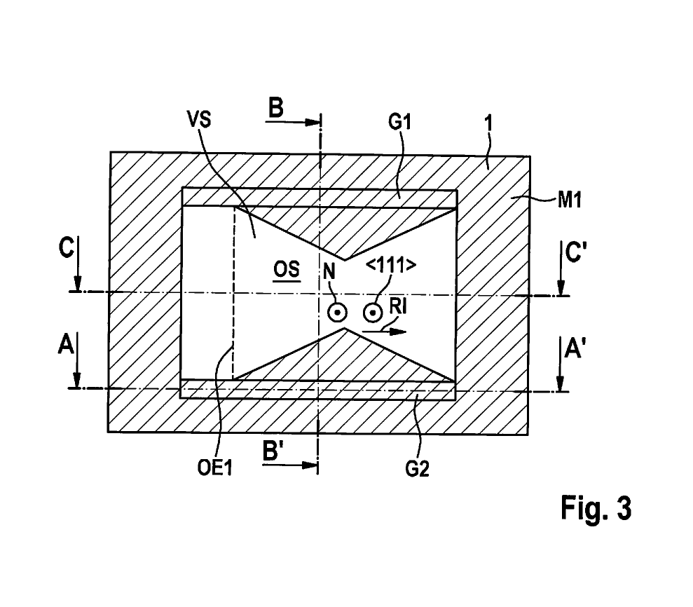

FIG. 3 is a schematic representation to illustrate a manufacturing method for a micromechanical device including an oblique surface and the corresponding micromechanical device according to a third example embodiment of the present invention.

In the third example embodiment shown in FIG. 3, first opening area OE1 of first etching mask M1 is not a rectangle as in the first and second example embodiments, but includes a narrowing area VS, which is formed by triangular mask portions of first etching mask M1, and which forms an etching allowance during the anisotropic etching with the aid of KOH.

Narrowing area VS delays in particular the impingement of the etching front on boundary areas which are defined by trenches G1, G2.

Of course, it is also possible to provide such a narrowing area in second etching mask M′ on rear side RS in the above-described second example embodiment.

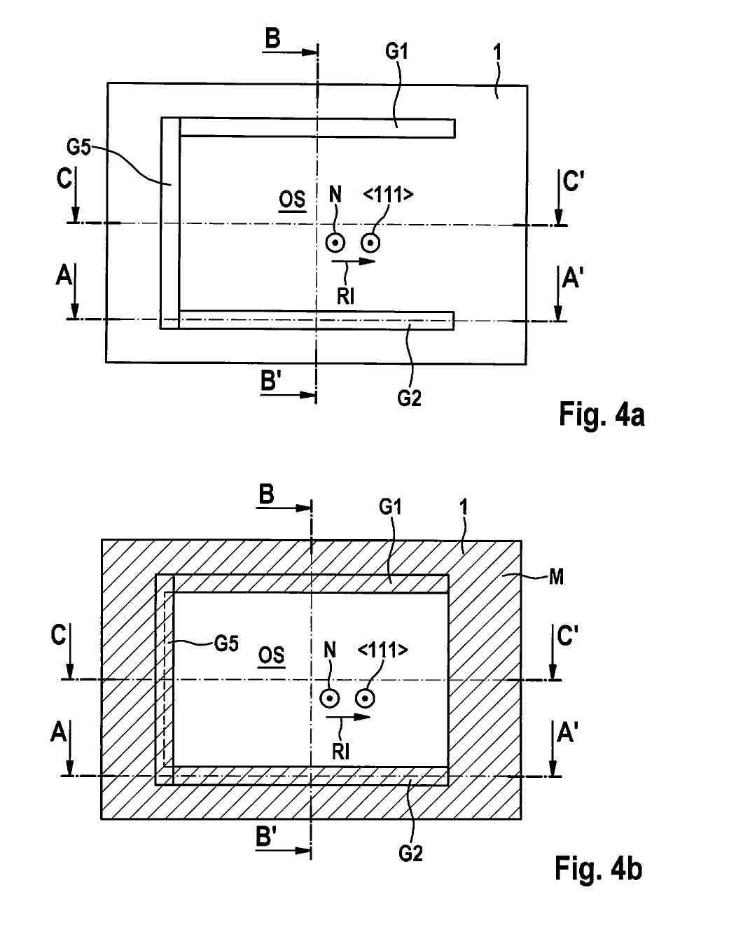

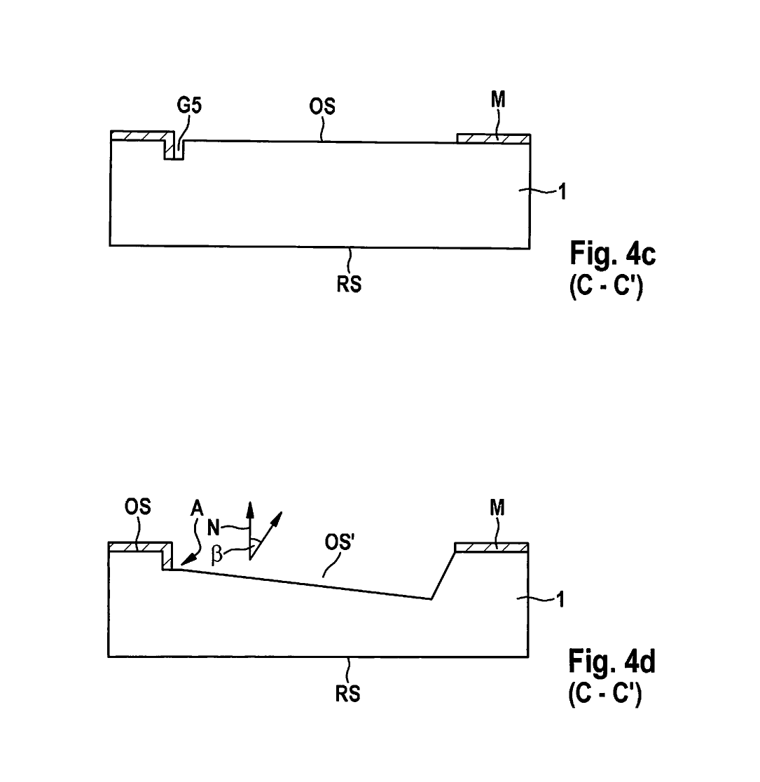

FIGS. 4a-4d are schematic representations to illustrate a manufacturing method for a micromechanical device including an oblique surface and the corresponding micromechanical device according to a fourth example embodiment of the present invention.

The illustration according to FIG. 4a corresponds to the illustration according to FIG. 1a, additionally a fifth trench G5 being formed in front side OS, which adjoins the end faces of first trench G1 and of second trench G2, which are situated on a side opposite direction RI of the deviation. Fifth trench G5 closes the end faces of first trench G1 and of second trench G2 into a U shape. Fifth trench G5 preferably has a smaller depth extension than first trench G1 and second trench G2, for example a smaller depth extension between 5 μm and 100 μm. In this way, a step can be set in the area of fifth trench G5 during the later anisotropic etching, as is described below.

As is shown in FIG. 4b, first etching mask M is formed in such a way that the U-shaped area enclosed by the U shape of first trench G1, second trench G2 and fifth trench G5 and approximately half the width of fifth trench G5 are opened.

FIG. 4c shows a vertical cross section along line C-C′ of FIG. 4b.

Subsequent to the process state shown in FIG. 4c, the anisotropic KOH etching process is carried out on front side OS using etching mask M. Again, the anisotropic etching process extends essentially up to a depth extension of first trench G1 or second trench G2. In this example embodiment, a step A is formed in the area of fifth trench G5, which is able to offer advantages during an optional later installation of an optical window F after through-opening TR has been formed. Such a step A offers a stop for the optical window. The height of the step is predefined by the depth of fifth trench G5.

Otherwise, the fourth example embodiment extends in the same manner as the above-described first example embodiment.

Of course, such a further trench, which forms a U shape, can also be formed in the shape of a sixth trench on rear side RS between third trench G3 and fourth trench G4.

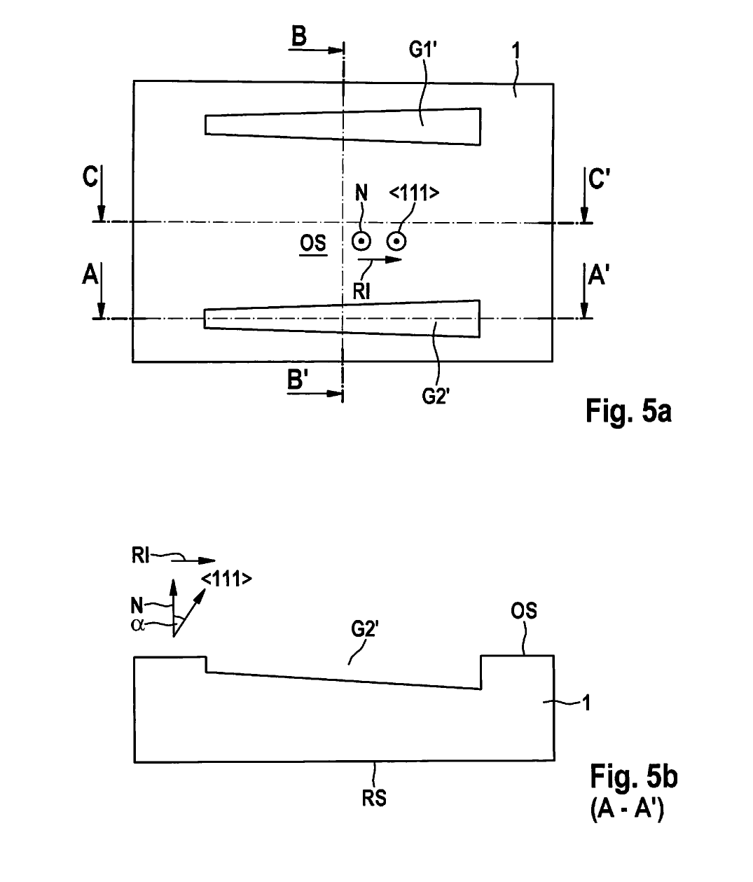

FIGS. 5a-5b are schematic representations to illustrate a manufacturing method for a micromechanical device including an oblique surface and the corresponding micromechanical device according to a fifth example embodiment of the present invention.

In the fifth example embodiment, according to FIG. 5a the first trench is denoted by reference numeral G1′ and the second trench by reference numeral G2′. As is shown, first trench G1′ and second trench G2′ simultaneously widen and deepen in direction RI of the deviation. For this purpose, the so-called aspect ratio dependent etching (ARDE) effect can be utilized. The ARDE effect is understood to mean the dependence of the etching rate on the structural width of the trench. An oblique trench can thus also be achieved by laser ablation.

FIG. 5b shows a vertical section along line A-A′ of FIG. 5a.

Of course, it is also possible to provide such a widening and deepening on third trench G3 and on fourth trench G4 on rear side RS in the second example embodiment.

Although the present invention has been described based on preferred exemplary embodiments, it is not limited thereto. In particular, the described materials and topologies are shown only by way of example and are not limited to the described examples.

What is claimed is:

1. A method of manufacturing a micromechanical device t, the method comprising:
providing a silicon substrate having a front side and a rear side, wherein a first normal of the front side deviates by a first angle from a <111> direction of the silicon substrate, a lateral offset between the first normal and the <111> direction thereby increasing in a first offset direction;
forming a first trench and a second trench in the front side, the second trench being spaced apart from and essentially parallel to the first trench, and the first trench and the second trench extending along the first offset direction;
forming a first etching mask on the front side, which covers the front side except for a first opening area situated between the first trench and the second trench; and
anisotropically etching the front side, using the etching mask, thereby forming in the opening area an oblique surface having a second angle to the first normal, which approximately corresponds to the first angle.

2. The manufacturing method of claim 1, wherein:
a second normal of the rear side has the deviation by the first angle from the direction, a lateral offset between the second normal and the direction thereby increasing in a second offset direction opposite to the first offset direction; and
the method further comprises:
forming a third trench and a fourth trench in the rear side, the third trench being spaced apart from and essentially parallel to the fourth trench, and the third trench and the fourth trench extending along the opposite direction;
forming a second etching mask on the rear side, which covers the rear side except for a second opening area situated between the third trench and the fourth trench; and
simultaneously carrying out the anisotropic etching process on the rear side, using the etching mask, whereby a further oblique surface is formed in the second opening area having the second angle to the second normal, which approximately corresponds to the first angle, the further oblique surface extending essentially in parallel to the oblique surface.

3. The manufacturing method of claim 2, wherein the third trench runs in parallel to and laterally offset from the first trench, and the fourth trench runs in parallel to and laterally offset from the second trench.

4. The manufacturing method of claim 2, wherein the first opening area is essentially rectangular, extending up to a respective side edge and end edge of the first trench and of the second trench, and the second opening area is essentially rectangular, extending up to a respective side edge and end edge of the third trench and of the fourth trench.

5. The manufacturing method of claim 2, wherein the first etching mask fills the first trench and the second trench only partially and the second etching mask fills the third trench and the fourth trench only partially.

6. The manufacturing method of claim 2, wherein the depth extension of the first trench and of the second trench is identical, the anisotropic etching process being carried out at most up to the depth extension, and the depth extension of the third trench and of the fourth trench is identical to the depth extension of the first trench and of the second trench.

7. The manufacturing method of claim 2, further comprising forming a through-opening through the silicon substrate in a portion of the oblique surface, bonding an optical window onto the periphery of the portion of the oblique surface x, forming a through-opening through the silicon substrate in a portion of the further oblique surface, and bonding an optical window onto the periphery of the portion of the further oblique surface.

8. The manufacturing method of claim 2, further comprising forming a fifth trench in the rear side and adjoining end faces of the third and fourth trenches that are situated on a side opposite the first offset direction, the fifth trench closing the end faces into a U shape.

9. The manufacturing method of claim 2, wherein the first trench and the second trench widen and deepen in the first offset direction the third trench and the fourth trench widen and deepen in the second offset direction.

10. The manufacturing method of claim 1, wherein the first opening area is essentially rectangular, extending up to a respective side edge and end edge of the first trench and of the second trench.

11. The manufacturing method of claim 1, wherein the first etching mask fills the first trench and the second trench only partially.

12. The manufacturing method of claim 1, wherein the depth extension of the first trench and of the second trench is identical, the anisotropic etching process being carried out at most up to the depth extension.

13. The manufacturing method of claim 1, further comprising forming a through-opening through the silicon substrate in a portion of the oblique surface, and bonding an optical window onto the periphery of the portion of the oblique surface.

14. The manufacturing method of claim 1, wherein the first opening area of the first etching mask includes at least one narrowing area that defines an etching allowance during the anisotropic etching.

15. The manufacturing method of claim 1, further comprising forming a third trench in the front side and adjoining end faces of the first and second trenches that are situated on a side opposite the first offset direction, the third trench closing the end faces into a U shape.

16. The manufacturing method of claim 1, wherein the first trench and the second trench widen and deepen in the first offset direction.

17. The manufacturing method of claim 1, wherein the anisotropic etching process includes a KOH etching.

18. A micromechanical device comprising:
a silicon substrate with a front side and a rear side, wherein:
a first normal of the front side deviates by a first angle from a <111> direction of the silicon substrate; and
an oblique surface of the front side is at a second angle to the first normal, the second angle approximately corresponding to the first angle.
